(19) United States
(12) Patent Application Publication
(10) Pub. No.: US 2026/0317908 A1
(43) Pub. Date: Oct. 15, 2026

(54) INTEGRATION OF BARRIER COATINGS INTO FILM MANUFACTURE

(71) Applicant: Nfinite Nanotechnology Inc., Waterloo (CA)

(72) Inventors: Chee Hau Teoh, Kitchener (CA); Jhi Yong Loke, Waterloo (CA)

(73) Assignee: Nfinite Nanotechnology Inc., Waterloo, ON (CA)

(21) Appl. No.: 19/476,154

(22) PCT Filed: Apr. 19, 2024
(86) PCT No.: PCT/IB2024/053855

§ 371 Date: Oct. 16, 2025

Related U.S. Application Data
(60) Provisional application No. 63/460,517, filed on Apr. 19, 2023.

(51) Int. Cl. C23C 16/54; C23C 16/455

(52) U.S. Cl. CPC C23C 16/545; C23C 16/45544

(57) ABSTRACT

An example apparatus includes a first conveyance subsystem to transport a first flexible substrate along a first path, a printer positioned on the first path to apply a marking to the first flexible substrate, a dryer positioned on the first path downstream of the printer to dry the marking applied to the first flexible substrate by the printer, and a second conveyance subsystem to transport a second flexible substrate material along a second path. The apparatus further includes a spatial atomic layer deposition (SALD) head positioned on the first path or the second path and connectable to a gas-delivery subsystem to deliver gas to a respective one of the first flexible substrate and the second flexible substrate to form a barrier coating thereon.

### CROSS-REFERENCE TO RELATED APPLICATIONS

This application claims priority to and the benefit of U.S. provisional patent application No. 63/460,517, filed Apr. 19, 2023, which is incorporated herein by reference.

### FIELD

The present disclosure relates to coatings and deposition of coatings onto film, particularly, nanometer-scale coatings.

### BACKGROUND

Coatings are used on flexible materials for a wide range of packaging applications. Examples include, but are not limited to, coatings that protect the products contained in the packaging (e.g., foodstuffs) from external factors, coatings that provide antimicrobial properties (e.g., packaging for healthcare products), and coatings that serve other purposes.

Barrier coatings may be used on flexible packaging materials to protect products from external factors that include, but are not limited to, water vapor, water, oxygen, light, aromas, grease, and foreign matter. Protection from these external factors is useful to extend the shelf-life of the product and ensure it is safe for use or consumption.

### SUMMARY

According to an aspect of the present disclosure, an apparatus includes a first conveyance subsystem to transport a first flexible substrate along a first path, a printer positioned on the first path to apply a marking to the first flexible substrate, a dryer positioned on the first path downstream of the printer to dry the marking applied to the first flexible substrate by the printer, and a second conveyance subsystem to transport a second flexible substrate material along a second path. The apparatus further includes a spatial atomic layer deposition (SALD) head positioned on the first path or the second path and connectable to a gas-delivery subsystem to deliver gas to a respective one of the first flexible substrate and the second flexible substrate to form a barrier coating thereon.

The SALD head may be positioned on the first path downstream of the dryer.

The SALD head may be positioned on the first path upstream of the printer.

The SALD head may be positioned on the second path.

The first conveyance subsystem and the second conveyance subsystem may be arranged to merge the first path and the second path at a junction to form a third path along which the first flexible substrate and second flexible substrate are transported.

The apparatus may further include an extrusion coater positioned upstream of the junction to coat the first substrate or the second substrate with an adhesive to bond the first substrate and the second substrate.

The SALD head may form the barrier coating as an arrangement of alternating layers of different materials.

The apparatus may further include an air jet device positioned adjacent the SALD head to jet air or other gas at the respective one of the first flexible substrate and the second flexible substrate.

According to another aspect of the present disclosure, an apparatus includes a conveyance subsystem to transport a flexible substrate along a path, a pre-coat subsystem positioned on the path to apply a pre-coat to the flexible substrate to form a pre-coated flexible substrate, a spatial atomic layer deposition (SALD) head positioned on the path downstream of the pre-coat subsystem and connectable to a gas-delivery subsystem to deliver gas to the pre-coated flexible substrate to form a barrier coating thereon, and a top-coat subsystem positioned on the path downstream of the SALD head to apply a top coat to the barrier coating formed on the pre-coated flexible substrate to form a flexible packaging film.

The apparatus may further include a dryer positioned on the path between the pre-coat subsystem and the SALD head to dry the pre-coated flexible substrate.

The apparatus may further include a dryer positioned on the path downstream of the top-coat subsystem to dry the top coat.

The SALD head may form the barrier coating with an arrangement of alternating layers of different materials.

The top-coat subsystem may apply a heat sealable material as the top coat.

The apparatus may further include an air jet device positioned adjacent the SALD head to jet air or other gas at the pre-coated flexible substrate.

According to another aspect of the present disclosure, an apparatus includes a first conveyance subsystem to transport a first flexible substrate along a first path and a second conveyance subsystem to transport a second flexible substrate material along a second path. The first conveyance subsystem and the second conveyance subsystem are arranged to merge the first path and the second path at a junction to form a third path along which the first flexible substrate and second flexible substrate are transported. The apparatus further includes an extrusion coater positioned upstream of the junction to coat the first substrate or the second substrate with an adhesive to bond the first substrate and the second substrate. The apparatus further includes a spatial atomic layer deposition (SALD) head positioned on the first path or the second path and connectable to a gas-delivery subsystem to deliver gas to a respective one of the first flexible substrate and the second flexible substrate to form a barrier coating thereon.

The apparatus may further include an air jet device positioned adjacent the SALD head to jet air or other gas at the respective one of the first flexible substrate and the second flexible substrate.

### BRIEF DESCRIPTION OF THE DRAWINGS

FIG. 1 is a diagram of an apparatus to manufacture a film with a barrier coating using a spatial atomic layer deposition (SALD) head.

FIG. 2 is a diagram of another example apparatus to manufacture a film with a barrier coating using a SALD head, where the SALD head is positioned downstream of a dryer.

FIG. 3 is a diagram of another example apparatus to manufacture a film with a barrier coating using a SALD head, where the SALD head is positioned upstream of a printer.

FIG. 4 is a diagram of another example apparatus to manufacture a film with a barrier coating using a SALD head, where the SALD head is positioned along a material path different from a material path that contains a printer and dryer.

FIG. 5 is a diagram of another example apparatus to manufacture a film with a barrier coating using a SALD head, where the SALD head is positioned between a pre-coat subsystem and a top-coat subsystem.

FIG. 6 is a diagram illustrating an example spatial atomic layer deposition (SALD) process to deposit a barrier coating.

FIG. 7 is a diagram illustrating an example SALD apparatus to deposit a barrier coating.

FIG. 8 is a cross-sectional view of an example barrier coating disposed on a substrate, where the barrier coating includes bilayers with each bilayer having two layers of different materials.

FIG. 9 is a diagram of another example apparatus to manufacture a film with a barrier coating using a SALD head, in which a printer and a dryer are not used.

FIG. 10 is a diagram of an example arrangement of SALD heads with air jet devices.

FIG. 11 is a diagram of another example arrangement of SALD heads with air jet devices.

### DETAILED DESCRIPTION

The present disclosure relates to integration of spatial atomic layer deposition (SALD) coating heads with related components to achieve continuous or roll-to-roll production of coated films. Such integrations are made possible or made more efficient because the SALD heads discussed herein are open-air and are not required to be located within a vacuum chamber. Moreover, various coatings discussed herein are stable immediately or shortly after deposition, which also helps facilitate beneficial integrations. One advantage of such integrations is increased throughput, which reduces the time and cost in application SALD coatings.

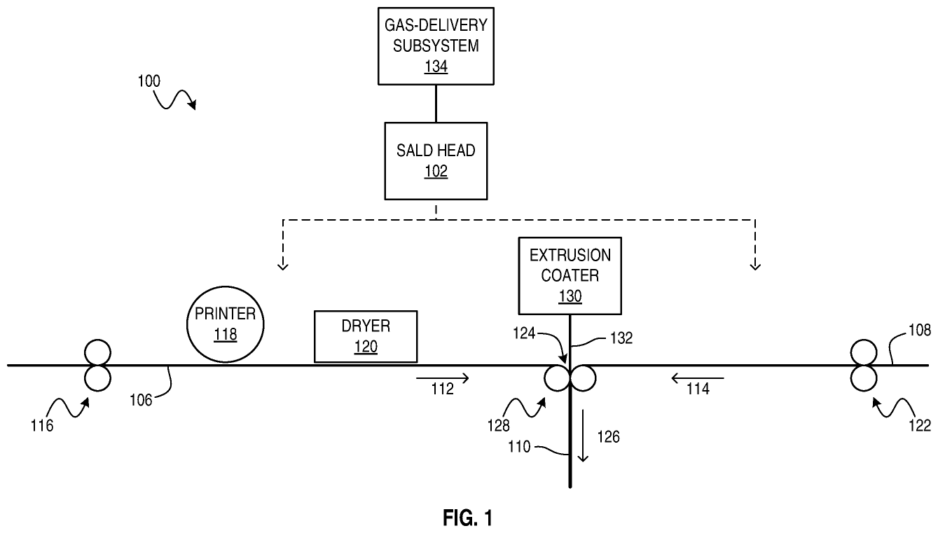

FIG. 1 shows an example apparatus 100 that includes a spatial atomic layer deposition (SALD) head 102 configured to deposit a barrier coating onto a flexible substrate 106, 108 to form a film 110. While the techniques discussed herein are particularly suited to barrier coatings, they are not limited to barrier coatings.

The film 110 may be used for packaging, such as food packaging (e.g., sealed bags or packages that contain food or ingredients, such as snacks, meat, cheese, etc.), personal care products (e.g., creams, lotions, gels, etc.), pharmaceuticals, sterile medical products or instruments, agricultural products, and similar products that benefit from protection against degradation or contamination and/or that require a relatively long shelf life. The substrate 106, 108 provides mechanical strength to the film 110 and the barrier coating provides a barrier against material (e.g., oxygen, water, gases, particles, contaminates, etc.) that may otherwise pass into or through the substrate 106, 108.

Packaging is a suitable application for the techniques discussed herein but is not the only application. As such, the present disclosure is not limited to packaging film. It should be apparent that the teachings and examples provided herein as related to packaging film may be used for or readily adapted to other applications.

The apparatus 100 is configured to merge multiple substrates 106, 108 to form the film 110 by way of adhesive or other bonding technique. Accordingly, a SALD head 102 may be provided to any of the transport paths 112, 114 used to convey a substrate 106, 108 to the point of merging.

The apparatus 100 includes a first conveyance subsystem 116 to transport a first flexible substrate 106 along a first path 112. The first conveyance subsystem 116 may include a roller, a web guide, a nip roller, an idler, a dancer, a load cell, and similar components to convey the flexible substrate 106. The first conveyance subsystem 116 may receive the first flexible substrate 106 from an upstream component, such as an unwinder that provides a roll of substrate material.

The apparatus 100 further includes a printer 118 positioned on the first path 112 to apply a marking to the first flexible substrate 106 as the first flexible substrate 106 is conveyed along the first path 112. Markings may include text, imagery, labels, logos, artwork, and other markings typically provided to packaging. The markings may be selectively deposited on the first flexible substrate 106 and need not cover the entire first flexible substrate 106.

The apparatus 100 further includes a dryer 120 positioned on the first path 112 at a location downstream of the printer 118. The dryer 120 dries the marking applied to the first flexible substrate by the printer 118.

The apparatus 100 includes a second conveyance subsystem 122 to transport a second flexible substrate 108 along a second path 114. The second conveyance subsystem 122 may include a roller, a web guide, a nip roller, an idler, a dancer, a load cell, and similar components to convey the flexible substrate 108. The second conveyance subsystem 122 may receive the second flexible substrate 108 from an upstream component, such as an unwinder that provides a roll of substrate material.

The first conveyance subsystem 116 and the second conveyance subsystem 122 may be arranged to merge the first path 112 and the second path 114 at a junction 124 to form a third path 126 along which the first flexible substrate 106 and second flexible substrate 108 are transported. The junction 124 may be defined by a third conveyance subsystem 128, which may include rollers or other components (see the first and second conveyance subsystems).

The apparatus may further include an extrusion coater 130 positioned upstream of the junction 124 to coat the first substrate 106 or the second substrate 108 with an adhesive 132 to bond the first substrate 106 and the second substrate 108 together. The adhesive 132 may take the form of a film or membrane may be a bulk material (e.g., liquid, gel, spray, etc.) that is applied to one or both substrates 106, 108. The first flexible substrate 106, the second flexible substrate 108, and the adhesive 132 merge at the junction 124. The substrates 106, 108 sandwich the adhesive 132 to form the film 110.

The extrusion coater 130 may be configured to apply the adhesive 132 or similar material using a solvent-based process, solventless process, extrusion lamination, and similar processes.

A SALD head 102 is positioned on the first path 112 or the second path 114. The term “or” as used herein is inclusive of more than one alternative and is synonymous with “and/or.” Any suitable number of SALD heads 102 may be provided to either or both paths 112, 114. The SALD head 102 is connectable to a gas-delivery subsystem 134 to deliver gas to the first flexible substrate 106 or the second flexible substrate 108, as the case may be, to form a barrier coating thereon. When more than one SALD head 102 is used, each SALD head 102 may be connected to its own gas-delivery subsystem 134 or several SALD heads may be connected to a common gas-delivery subsystem 134. A SALD head 102 may be configured to deposit one layer of a coating, multiple layers of a coating, or all the layers of a coating. When a SALD head 102 is configured to deposit fewer than all layers of a coating, more than one SALD head 102 may be used and, for example, may be positioned adjacent one another.

A method of operation includes the first conveyance subsystem 116 transporting the first substrate 106 along the first path 112 and the second conveyance subsystem 122 transporting the second substrate 108 along the second path 114, with the two substrates 106, 108 meeting at the junction 124. The printer 118 prints ink or other marking material onto the first substrate 106 to form an ink layer and the dryer 120 dries the ink layer. The SALD head 102 takes gas from the gas-delivery subsystem 134 and applies a barrier coating to the first substrate 106 or the second substrate 108. If positioned to apply the barrier coating to the first substrate 106, the SALD head 102 may apply the barrier coating above or below the ink layer. The first substrate 106 and the second substrate 108 are brought together at the junction 124 and bonded together, which may include the introduction of an adhesive 132 by an extrusion coater 130, to form a film 110.

In other examples, in addition to or as an alternative to the subsystem formed by the printer 118 and dryer 120, the apparatus 100 may include a lamination subsystem, a slitting subsystem, a cast film subsystem, a blown film subsystem, or similar subsystems for processing film.

Features and aspects of the apparatus 100 may be combined with other features and aspects of the other apparatuses discussed herein. Like terminology and like reference numerals denote like components which may be added to the apparatus 100 or used to replace component(s) of the apparatus 100.

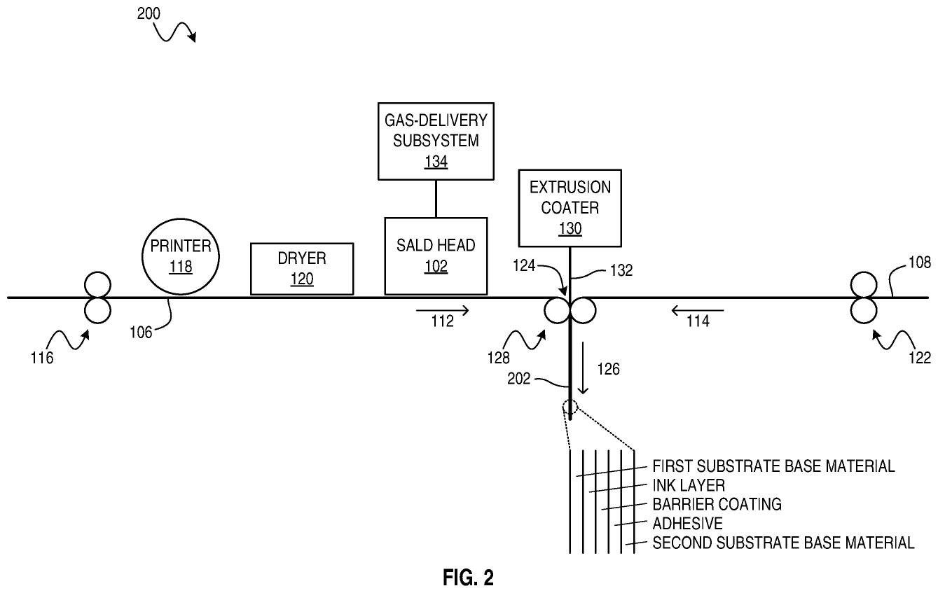

FIG. 2 shows another example apparatus 200 to manufacture a film 202 with a barrier coating using a SALD head 102. In this example, the SALD head 102 is positioned downstream of a dryer 120 that is downstream of a printer 118, so as to apply the barrier coating to a first substrate 106 that includes printed and dried marking material. In addition to drying marking material deposited by the printer 118, the dryer 120 may also help warm the substrate 106 to aid deposition of the barrier coating. For details concerning the other components of the apparatus 200, the above description related to FIG. 1 may be referenced.

The apparatus 200 makes a film 202 that has the following layers in order: first substrate base material, ink layer, barrier coating, adhesive, and second substrate base material. The term “substrate base material” is intended to refer to substrate material that has not yet been processed by the apparatus 200. A substrate base material may have one or multiple layers of the same material or different materials. The term “substrate” is intended to refer to a substrate base material that may have had some processing performed by the apparatus 200, such as the application of ink.

Features and aspects of the apparatus 200 may be combined with other features and aspects of the other apparatuses discussed herein. Like terminology and like reference numerals denote like components which may be added to the apparatus 200 or used to replace component(s) of the apparatus 200.

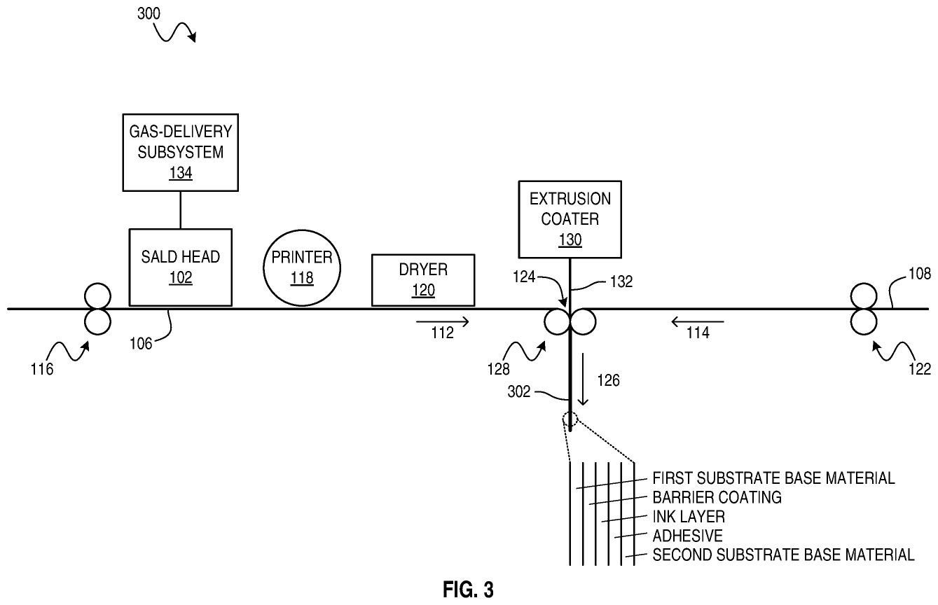

FIG. 3 shows another example apparatus 300 to manufacture a film 302 with a barrier coating using a SALD head 102. In this example, the SALD head 102 is positioned upstream of a printer 118, so as to apply the barrier coating to a first substrate 106 that does not yet include printed and dried marking material. The barrier coating would thus be positioned under an ink layer. For details concerning the other components of the apparatus 300, the above description related to FIG. 1 may be referenced.

The apparatus 300 makes a film 302 that has the following layers in order: first substrate base material, barrier coating, ink layer, adhesive, and second substrate base material.

Features and aspects of the apparatus 300 may be combined with other features and aspects of the other apparatuses discussed herein. Like terminology and like reference numerals denote like components which may be added to the apparatus 300 or used to replace component(s) of the apparatus 300.

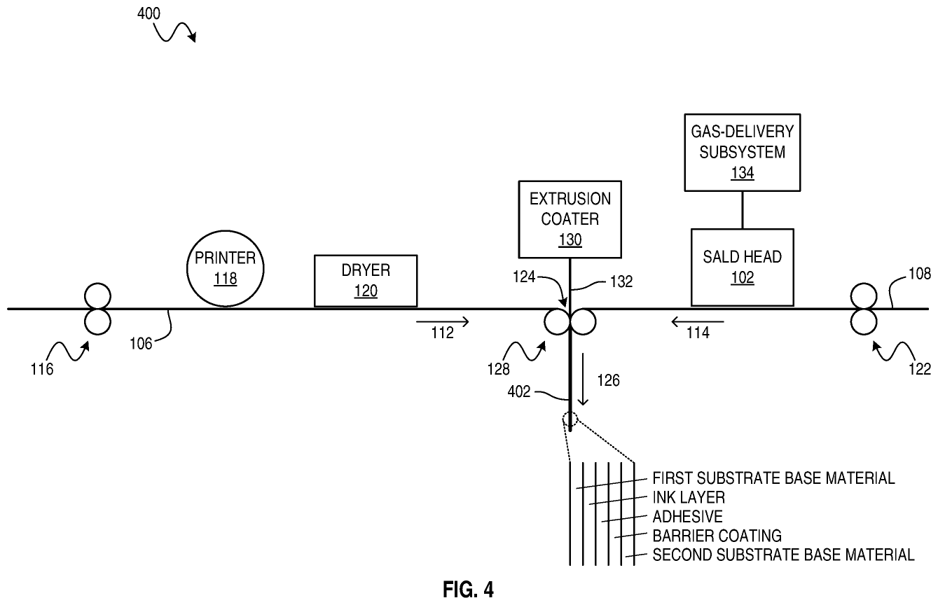

FIG. 4 shows another example apparatus 400 to manufacture a film 402 with a barrier coating using a SALD head 102. In this example, the SALD head 102 is positioned along a material path 114 different from a material path 112 that contains a printer 118 and dryer 120, so as to apply the barrier coating to a second substrate 108 that does not receive marking material. For details concerning the other components of the apparatus 400, the above description related to FIG. 1 may be referenced.

The apparatus 400 makes a film 402 that has the following layers in order: first substrate base material, ink layer, adhesive, barrier coating, and second substrate base material.

Features and aspects of the apparatus 400 may be combined with other features and aspects of the other apparatuses discussed herein. Like terminology and like reference numerals denote like components which may be added to the apparatus 400 or used to replace component(s) of the apparatus 400.

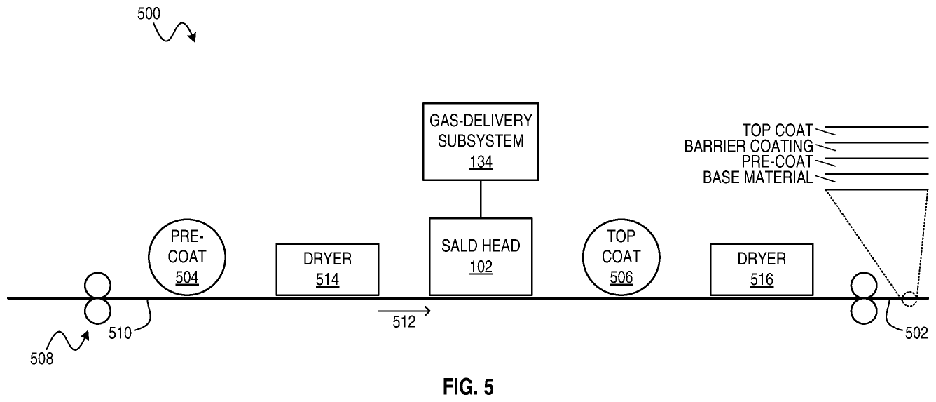

FIG. 5 shows another example apparatus 500 to manufacture a film 502 with a barrier coating using a SALD head 102. In the example, the SALD head 102 is positioned between a pre-coat subsystem 504 and a top-coat subsystem 506.

The apparatus 500 includes a conveyance subsystem 508 to transport a flexible substrate 510 along a path 512. For details concerning the conveyance subsystem 508, the above description related to conveyance subsystems 116, 122 of FIG. 1 may be referenced.

The apparatus 500 further includes a pre-coat subsystem 504 positioned on the path 512 to apply a pre-coat to the flexible substrate 510 to form a pre-coated flexible substrate. A pre-coat may be referred to as a primer.

The apparatus 500 further includes a SALD head 102 positioned on the path 512 downstream of the pre-coat subsystem 504 and connectable to a gas-delivery subsystem 134 to deliver gas to the pre-coated flexible substrate to form a barrier coating thereon. For detail concerning the SALD head 102 and gas-delivery subsystem 134, the above description related to FIG. 1 may be referenced.

The apparatus 500 further includes a top-coat subsystem 506 positioned on the path 512 downstream of the SALD head 102 to apply a top coat to the barrier coating formed on the pre-coated flexible substrate, so as to form a flexible packaging film 502. A heat sealable material may be used as the top coat, so as to aid the making of packages with the film 502. In other examples, other top coat materials may be additionally or alternatively used to provide different useful structures and functions. A top coat may protect the barrier coating and further improve the barrier function of the film 502 as a whole, for example, by improving the water vapor transmission rate (WVTR). For instance, a top coat material such as polyethylene may provide for heat sealing and improve the WVTR of the film 502.

The apparatus 500 may further include a dryer 514 positioned on the path 512 between the pre-coat subsystem 504 and the SALD head 102 to dry the pre-coated flexible substrate prior to deposition of the barrier coating. In addition to drying pre-coat material applied by the pre-coat subsystem 504, the dryer 514 may also help warm the substrate 510 to aid deposition of the barrier coating.

The apparatus 500 may further include a dryer 516 positioned on the path 512 downstream of the top-coat subsystem 506 to dry the top coat after application of the top coat over the barrier coating.

The apparatus 500 makes a film 502 that has the following layers in order: base material, pre-coat, barrier coating, and top coat.

Features and aspects of the apparatus 500 may be combined with other features and aspects of the other apparatuses discussed herein. Like terminology and like reference numerals denote like components which may be added to the apparatus 500 or used to replace component(s) of the apparatus 500.

The above example arrangements are not intended to be limiting. In various other examples, the techniques discussed herein may be used to manufacture films with similar structures, such as, a base material with a pre-coat and a barrier coating or a base material with a barrier coating and a top coat. To achieve these examples, the respective top-coat or pre-coat subsystem may be omitted or deactivated. This applies to any of the other examples herein. The example arrangements described may omit one or more layers by omitted or turning off the respective component(s).

Regarding materials, substrate base material may include polylactic acid (PLA), paper, paperboard, polyethylene terephthalate (PET), polypropylene (PP), polyethylene (PE), polyurethane (PU), polyhydroxyalkanoates (PHA), polyhydroxybutyrate (PHB), starch-based polymer, seaweed-based polymer, or similar. The substrate base material may include additional materials or layers thereof, such as an ink layer or pre-coat (also termed a primer). Substrate base material may be selected to be biodegradable, recyclable, or compostable.

Useful substrates may have a broad range of surface chemistries. Oxygen (O) groups at the surface are particularly useful. A precursor chemical used when forming the barrier coating may react with O groups, which facilitates coating deposition. Examples of base materials and primers that have such O groups include PLA, PET, polyvinyl alcohol (PVOH), ethylene vinyl alcohol (EVOH), and acrylic, for example.

No particular treatment to enhance surface energy is required for the substrate, as it has been found that the barrier coating adheres satisfactorily to the substrate without such treatment.

Inline surface treatment may help remove dust and particles to improve surface cleanliness and prevent pinhole formation. Example surface treatments (also termed pretreatment) include corona treatment, plasma treatment (e.g., argon plasma), and flame treatment. Pretreating the surface prior to applying the barrier coating may help with coating deposition by, for example, smoothing the surface in a way that improves the bonding of the coating. The barrier coating may conformally coat the surface and encapsulate any dust particles and thus surface treatment may be used but is not expected to be required in many cases.

A substrate may include any one or combination of a skin layer, primer (pre-coat) layer, and pretreatment, on one or both sides.

The barrier coating may include an oxide, a metal oxide, an alkoxide, a metalcone (e.g., an “alucone” or “zincone”), oxynitride, or similar material. For example, the barrier coating may include a layer of aluminum oxide and a layer of zinc oxide. Aluminum oxide may act as the main gas barrier material. Zinc oxide may act as a structural layer and may provide other benefits, such as ultraviolet (UV) light blocking. In various examples, the barrier coating is configured so that an aluminum oxide layer contacts the substrate. In other examples, the barrier coating is configured so that a zinc oxide layer contacts the substrate, which may improve barrier performance against moisture. The substrate-contacting layer (which may be termed a nucleation layer) may be thicker than the other layers. In still other examples, other materials, such as tin oxide, silicon oxide, and titanium dioxide, may be used.

Example materials for the pre-coat include PVOH, EVOH, acrylic, polyurethane (PU), nanocellulose/micro fibrillated cellulose, PLA coating, PE coating, or similar.

Example top coat materials include a PE layer for heat sealing and other materials discussed above as useful for the pre-coat.

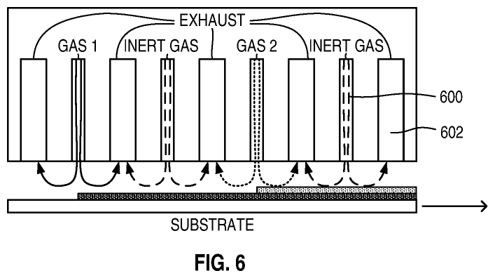

With reference to FIG. 6, the barrier coatings discussed herein may be deposited onto a substrate using a SALD head 102. FIG. 6 shows the basic elements of an example SALD head useful as the SALD head 102. The SALD process generally includes ejecting working gas (e.g., precursor gas, reactant gas, inert gas, etc.) via one or more slits 600 and withdrawing exhaust gas via one or more slits 602, in which the slits 600, 602 communicate the gas with a network of channels within a structure that may be termed a SALD coater or head. This reduces or eliminates the need for evacuation and purge steps that make traditional ALD slow, such that SALD can be one to two orders of magnitude faster than conventional ALD. SALD can produce ultra-thin coatings of materials (e.g., metal oxides) that are compact, conformal, and pinhole-free and can deposit the coatings under open-air conditions and pressures, and at room or low temperatures, without the need for a vacuum chamber. SALD is scalable and compatible with roll-to-roll manufacturing and has been demonstrated to work on variety of surfaces including, but not limited to, plastics and paper. More information on ALD and SALD can be found in PCT publication WO2021119829, entitled “Apparatus and Method for Thin Film Deposition”, filed on Dec. 18, 2020, which is incorporated herein by reference. Additional information concerning exhaust management in SALD systems and SALD heads can be found in PCT publication WO2024075062, which is incorporated herein by reference.

Features and aspects of the apparatus of FIG. 6 may be combined with other features and aspects of the other apparatuses discussed herein.

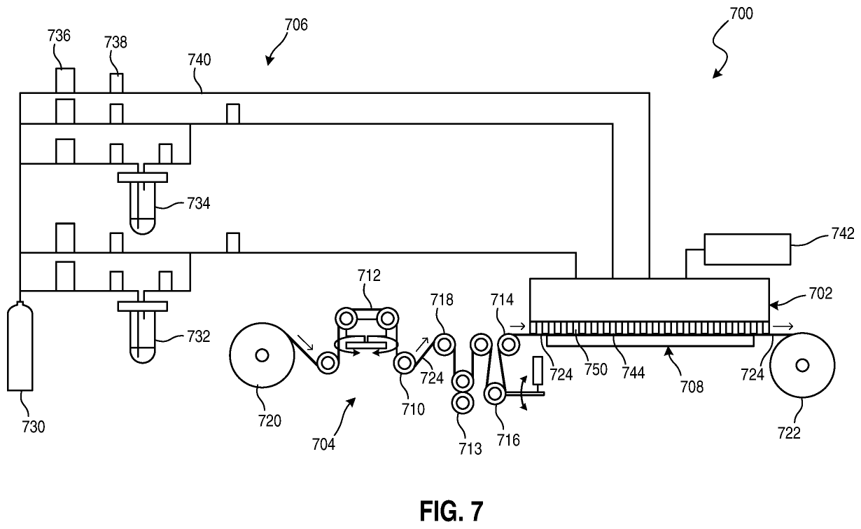

FIG. 7 shows an example spatial atomic layer deposition apparatus 700 operable to deposit a barrier coating. The apparatus 700 includes a SALD head 702, a conveyance system 704, and a gas-delivery system 706. A heater 708 may be provided at the SALD head 702. Any suitable number of SALD heads 702 may be used to deliver any suitable combination of gases by the gas-delivery system 706 to deposit a barrier coating onto a flexible substrate conveyed past the SALD head 702 by the conveyance system 704. The flexible substrate may be conveyed in one or both directions past one or multiple SALD heads 702 to build up the barrier coating.

The conveyance system 704 may include rollers 710, web guides 712, nip rollers 713, idlers 714, dancers 716, load cells 718, and like components positioned between an unwinder 720 and a winder 722 to convey a flexible substrate material 724, such as a thin sheet or membrane of material (sometimes called a “film,” particularly in the packaging industry, but this is not to be confused with the thin film or coating being deposited). With the conveyance system 704, the flexible substrate material 724 may be unwound from a roll at the unwinder 720, coated by the SALD head 702, and wound onto another roll at the winder 722. The positioning of the rollers may be used to position flexible material relative to one or more SALD heads 702 and may be used to control the distance between the surface of the flexible material 724 and the surface of the SALD head 702.

The gas-delivery system 706 includes vessels 730, 732, 734 with inert gas (e.g., nitrogen), precursor (e.g., trimethylaluminum, Al(CH₃)₃, for aluminum oxide), and reactant (e.g., an oxidant such as H₂O), mass flow controllers 736, on-off valves 738, and gas lines 740 that fluidly connect these components. Each gas line 740 may deliver to the SALD head 702 pure or a mixture of an inert gas, precursor, and reactant, at a flow rate controlled by respective mass flow controller(s) 736 and on-off valve(s) 738. The configuration and arrangement of the components in FIG. 7 represent an example. In other examples, the components may have different configurations and arrangements.

The gas lines 740 may be tubes made of chemically stable or inert material, such as stainless steel or Teflon, connected between components upstream of the SALD head 702. Such components may include an inert gas vessel 730, chemical-containing vessels (e.g., bubblers) 732, 734, mass flow controllers 736, and on-off valves 738. This gas delivery system 706 serves the purpose of delivering one or more precursor gases, one or more reactant gases, and one or more inert gases, in pure form or suitable mixtures, to the SALD head 702. The inert gas vessel 730 supplies inert, non-reactive gas to the SALD head 702 and may also be used to carry precursor gas from a precursor gas vessel 734 and/or reactant gas from a reactant gas vessel 732 to the SALD head 702. The pressure of the inert gas may be regulated by one or more pressure regulators. The precursor and reactant gases may be generated by techniques such as, but not limited to, bubbling a liquid chemical with the inert gas, nebulizing a liquid chemical, by heating a liquid or solid chemical, direct liquid injection where a liquid chemical precursor is introduced to a vaporizer which vaporizes the liquid and ejects gas out of a nozzle, or a combination thereof. Chemical vapors may also be supplied in the gaseous state from a storage tank, or generated by another device, such as an ozone generator, which may be used to generate a reactant gas. The flow rates of the inert gas, one or more precursor gases, and one or more reactant gases are controlled by mass flow controllers 736 and on-off valves 738, such as manual diaphragm valves or pneumatic valves. The flow controllers 736 and valves 738 may be controlled manually or electronically by a control system.

Illustrated in FIG. 7, one or more SALD heads 702 deliver a precursor, reactant, and inert gas onto a flexible substrate material 724. The head 702 comprises multiple internal gas channels that redirect and distribute the gases out onto the flexible material 724 in an appropriate arrangement to result in SALD, as illustrated in FIG. 6. The head 702 includes any suitable number and configuration of slits 750 to output gas to the flexible substrate material 724. Other components may be integrated into one or more SALD heads 702, including, but not limited to, cooling and heating elements and plasma sources. For example, one or more plasma sources may be embedded into the head to lower the temperature required for the coating deposition. According to FIG. 7, one or more exhaust pumps 742 are connected to the head 702. The exhaust pump 742 removes gases such as unreacted precursor and/or reactant and inert gas from the space between the operating surface 744 of the head 702 and the surface of the flexible material 724.

Illustrated in FIG. 7, the heater 708 may be used to heat the flexible material 724 to facilitate chemical reactions on the surface of the flexible material 724. In the example shown, the heater 708 spans the length of the head 702. Various heaters with different heating power and with different shapes and sizes (e.g., a drum heater that the flexible material wraps around) may be provided. Additionally, one or more heaters may be embedded into the head 702. One or more heaters may also be used to control the position of the surface of the flexible material relative to one or more of the SALD heads 702, based on the mechanical positioning of the heater(s). One or more of the rollers of the conveyance system 704 may be heated to control the temperature of the flexible material 724.

In other examples, a sheet or multiple sheets of flexible material can be mounted on a translating stage which moves past the head either in a single-direction or in both directions for the coating process. The translating stage may be heated and may be used to control the distance between the surface of the flexible material and the surface of a SALD head 702.

More information concerning examples of the gas delivery system, SALD head(s), exhaust pump(s), heater(s), and translating stage can be found in PCT publication WO2021119829.

Features and aspects of the apparatus 700 may be combined with other features and aspects of the other apparatuses discussed herein. Like terminology and like reference numerals denote like components which may be added to the apparatus 700 or used to replace component(s) of the apparatus 700.

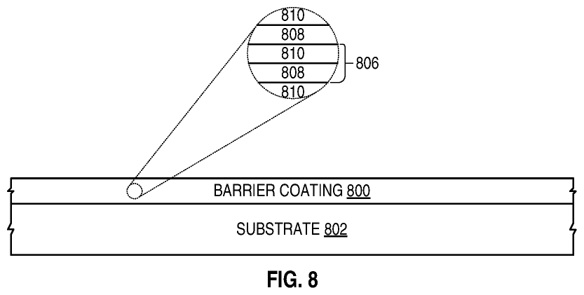

With reference to FIG. 8, a barrier coating 800 discussed herein may be configured with an arrangement of alternating layers of different materials. The barrier coating 800 is shown as deposited on a substrate 802, which may be a base material, a base material with an ink layer, or a base material with a pre-coat, as discussed above.

The barrier coating 800 may include a stack of bilayers 806. Any suitable number of nano-scale bilayers 806 may be used. Each bilayer 806 includes two layers of different materials 808, 810 that may be selected from the examples discussed above. The term “two” and similar terms used herein are open-ended unless otherwise specified. In this example, two layers means two or more layers, and a bilayer may be a tri-layer, etc. Examples of bilayer coatings are shown and described in PCT/IB2024/053370, which is incorporated herein by reference.

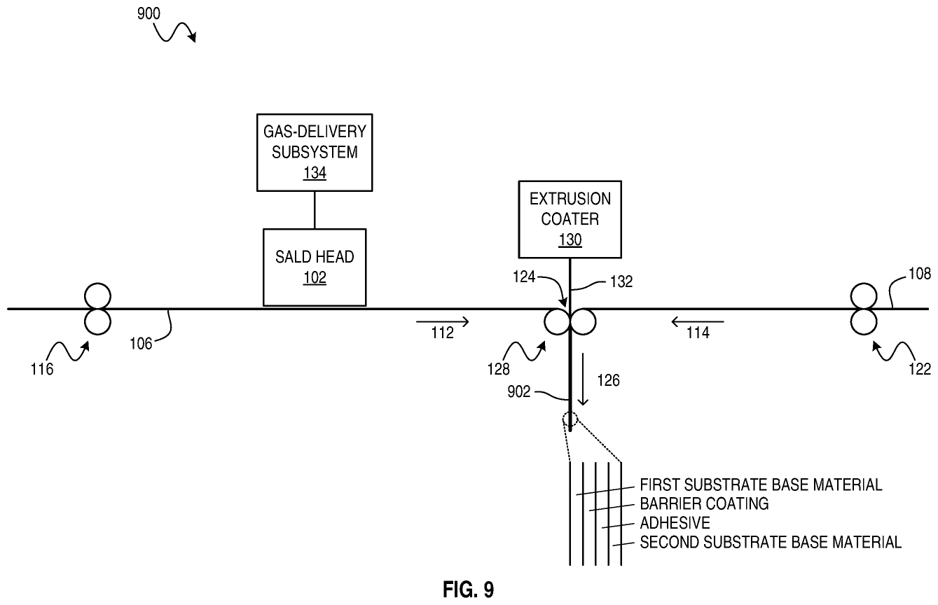

FIG. 9 shows another example apparatus 900 to manufacture a film 902 with a barrier coating using a SALD head 102 that is positioned at a first transport path 112. In this example, a printer and dryer are not used. The barrier coating is positioned between a first substrate 106 conveyed along the first path 112 and an adhesive 132 that bonds to a second substrate 108 that is conveyed along a second transport path 114. Additionally or alternatively, a SALD head 102 may be positioned at the second path 114. For details concerning the other components of the apparatus 900, the above description related to FIG. 1 may be referenced.

The apparatus 900 makes a film 902 that has the following layers in order: first substrate base material, barrier coating, adhesive, and second substrate base material.

Features and aspects of the apparatus 900 may be combined with other features and aspects of the other apparatuses discussed herein. Like terminology and like reference numerals denote like components which may be added to the apparatus 900 or used to replace component(s) of the apparatus 900.

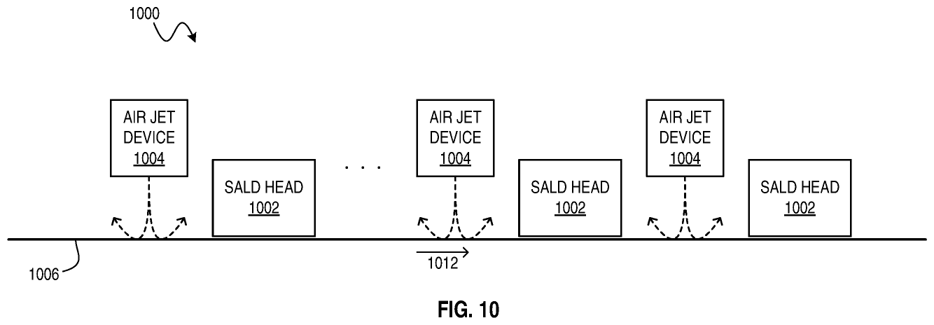

FIG. 10 shows an arrangement 1000 of SALD heads 1002 with air jet devices 1004.

Multiple SALD head 1002 are positioned along a transport path 1012 of a flexible substrate 1006. Each SALD head 1002 may be similar or identical to the SALD head 102 discussed above. Each SALD head 1002 may deposit one or more layers of coating material onto the substrate 1006.

An air jet device 1004 may be positioned adjacent a SALD head 1002 downstream of the SALD head 1002, with respect to the direction of motion of the substrate 1006 along the path 1012. In various examples, an air jet device 1004 may be positioned downstream of each SALD head 1002, as depicted.

An air jet device 1004 emits one or more jets of air (or other gas, such as nitrogen) along the width of the substrate 1006 to clean the substrate 1006 of debris or particulates, such as powder, prior to the substrate reaching the next piece of process equipment, such as the next SALD head 1002. This may help clear the substrate of excess powder, which may be formed by the reacting gasses of the upstream SALD head 1002 as a byproduct of forming a layer of coating. Clearing excess powder may reduce or eliminate flaws in subsequent layers of coating deposited by a downstream SALD head 1002.

An air jet device 1004 may be referred to as an air knife or air blade.

In other examples, an air jet device 1004 may be positioned upstream of each SALD head 1002, between adjacent SALD heads, or at some other suitable interval along the transport path 1012.

Features and aspects of the arrangement 1000 may be combined with other features and aspects of the other apparatuses discussed herein. Like terminology and like reference numerals denote like components which may be added to the arrangement 1000 or used to replace component(s) of the arrangement 1000. For example, an air jet device 1004 may be positioned downstream or upstream, with respect to substrate motion, of the SALD head 102 discussed in the examples of FIGS. 1-5 and 9.

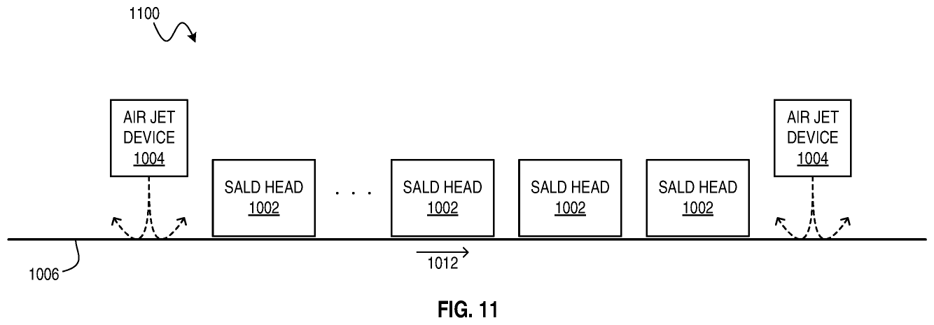

FIG. 11 shows an arrangement 1100 of SALD heads 1002 with air jet devices 1004. The description of FIG. 10 may be referenced for details not repeated here.

Multiple SALD head 1002 are positioned along a transport path 1012 of a flexible substrate 1006. Each SALD head 1002 may be similar or identical to the SALD head 102 discussed above. Each SALD head 1002 may deposit one or more layers of coating material onto the substrate 1006.

Air jet devices 1004 are positioned upstream of the first SALD head 1002 and downstream of the last SALD head 1002. The upstream air jet device 1004 cleans the substrate 1006 of any unwanted material (e.g., particulates, dust, etc.) that may detrimentally affect coating deposition. The downstream air jet device 1004 cleans the substrate 1006 of any powder or other materials remaining from coating deposition, so that downstream processes are not detrimentally affected. In this example, jet devices 1004 are not positioned between adjacent SALD heads 1002.

As should be understood from the examples of FIGS. 10 and 11, an air jet device 1004 may be positioned upstream of a SALD head, downstream of a SALD head, or between SALD heads. In various examples, any suitable number and positioning of air jet devices 1004 may be used.

Features and aspects of the arrangement 1100 may be combined with other features and aspects of the other apparatuses discussed herein. Like terminology and like reference numerals denote like components which may be added to the arrangement 1100 or used to replace component(s) of the arrangement 1100.

It should be recognized that features and aspects of the various examples provided above can be combined into further examples that also fall within the scope of the present disclosure. In addition, the figures are not to scale and may have size and shape exaggerated for illustrative purposes.

1. An apparatus comprising:
a first conveyance subsystem to transport a first flexible substrate along a first path;
a printer positioned on the first path to apply a marking to the first flexible substrate;
a dryer positioned on the first path downstream of the printer to dry the marking applied to the first flexible substrate by the printer;
a second conveyance subsystem to transport a second flexible substrate material along a second path; and
a spatial atomic layer deposition (SALD) head positioned on the first path or the second path and connectable to a gas-delivery subsystem to deliver gas to a respective one of the first flexible substrate and the second flexible substrate to form a barrier coating thereon.

2. The apparatus of claim 1, wherein the SALD head is positioned on the first path downstream of the dryer.

3. The apparatus of claim 1, wherein the SALD head is positioned on the first path upstream of the printer.

4. The apparatus of claim 1, wherein the SALD head is positioned on the second path.

5. The apparatus of claim 1, wherein:
the first conveyance subsystem and the second conveyance subsystem are arranged to merge the first path and the second path at a junction to form a third path along which the first flexible substrate and second flexible substrate are transported; and
the apparatus further comprises an extrusion coater positioned upstream of the junction to coat the first substrate or the second substrate with an adhesive to bond the first substrate and the second substrate.

6. The apparatus of claim 1, wherein the SALD head is to form the barrier coating as an arrangement of alternating layers of different materials.

7. The apparatus of claim 1, further comprising an air jet device positioned adjacent the SALD head to jet air or other gas at the respective one of the first flexible substrate and the second flexible substrate.

8. An apparatus comprising:
a conveyance subsystem to transport a flexible substrate along a path;
a pre-coat subsystem positioned on the path to apply a pre-coat to the flexible substrate to form a pre-coated flexible substrate;
a spatial atomic layer deposition (SALD) head positioned on the path downstream of the pre-coat subsystem and connectable to a gas-delivery subsystem to deliver gas to the pre-coated flexible substrate to form a barrier coating thereon; and
a top-coat subsystem positioned on the path downstream of the SALD head to apply a top coat to the barrier coating formed on the pre-coated flexible substrate to form a flexible packaging film.

9. The apparatus of claim 8, further comprising:
a dryer positioned on the path between the pre-coat subsystem and the SALD head to dry the pre-coated flexible substrate.

10. The apparatus of claim 8, further comprising:
a dryer positioned on the path downstream of the top-coat subsystem to dry the top coat.

11. The apparatus of claim 8, wherein the SALD head is to form the barrier coating with an arrangement of alternating layers of different materials.

12. The apparatus of claim 8, wherein the top-coat subsystem is to apply a heat sealable material as the top coat.

13. The apparatus of claim 8, further comprising an air jet device positioned adjacent the SALD head to jet air or other gas at the pre-coated flexible substrate.

14. An apparatus comprising:
a first conveyance subsystem to transport a first flexible substrate along a first path;
a second conveyance subsystem to transport a second flexible substrate material along a second path, wherein the first conveyance subsystem and the second conveyance subsystem are arranged to merge the first path and the second path at a junction to form a third path along which the first flexible substrate and second flexible substrate are transported;
an extrusion coater positioned upstream of the junction to coat the first substrate or the second substrate with an adhesive to bond the first substrate and the second substrate; and
a spatial atomic layer deposition (SALD) head positioned on the first path or the second path and connectable to a gas-delivery subsystem to deliver gas to a respective one of the first flexible substrate and the second flexible substrate to form a barrier coating thereon.

15. The apparatus of claim 14, further comprising an air jet device positioned adjacent the SALD head to jet air or other gas at the respective one of the first flexible substrate and the second flexible substrate.
